(19) United States
(12) Patent Application Publication
(10) Pub. No.: US 2026/0247668 A1
(43) Pub. Date: Aug. 20, 2026

(54) FAST RECOVERY DIODE WITH INTEGRATED CURRENT LIMITING RESISTOR

(71) Applicant: IPOWER SEMICONDUCTOR, GILROY, CA (US)

(72) Inventor: HAMZA YILMAZ, GILROY, CA (US)

(73) Assignee: IPOWER SEMICONDUCTOR, GILROY, CA (US)

(21) Appl. No.: 19/647,789

(22) Filed: Apr. 14, 2026

Related U.S. Application Data
(62) Division of application No. 18/404,549, filed on Jan. 4, 2024.

(51) Int. Cl. H10D 62/10; H10D 1/43; H10D 8/00; H10D 64/00

(52) U.S. Cl. CPC H10D 62/106; H10D 1/43; H10D 8/00; H10D 62/126; H10D 64/117

(57) ABSTRACT

A fast recovery diode may include: a first semiconductor structure including a first layer having a first conductivity type; a first electrode contacting a bottom surface of the first layer; a second semiconductor structure including a second layer having a second conductivity type, the second layer contacting the first semiconductor structure to form a junction; a second electrode of the diode, the second electrode overlying the second semiconductor structure; and a resistive semiconductor region providing a current path between the second electrode and the second semiconductor structure. The resistive semiconductor region may be formed in the second layer with an underlying buried layer defining a current path through the resistive semiconductor region or may be formed of polysilicon with insulating layers defining a current path through the resistive semiconductor region.

### CROSS REFERENCE TO RELATED APPLICATION

This application is a divisional patent application of U.S. Patent Application No. 18/404,549 filed on January 4, 2024, which is expressly incorporated by reference herein in its entirety.

### BACKGROUND OF THE INVENTION

Fast Recovery Diodes (FRDs) are key components of power electronics circuits for many applications, including motor-control applications. An FRD may be used alone or with a switching device such as an Insulated Gate Bipolar Transistor (IGBT). An FRD may particularly be connected in parallel with the IGBT to allow the IGBT to function properly when switching an inductive load. An FRD in such applications generally must be a soft recovery type diode having a low reverse recovery current (Irmax) or charge (Qrr) and a short reverse recovery time (Trr).

A commonly used technique to achieve a soft diode recovery is to have a carrier storage region above cathode region of the FRD. Two approaches have been used to shorten the reverse recovery time (Trr) and reduce reverse recovery current (Irmax) or charge (Qrr) of FRDs. One approach controls carrier injection by reduced anode doping concentration. Another approach shortens minority carrier lifetime by creating defect levels within an energy band gap near conduction and valence bands. Gold (Au) or platinum (Pt) diffusion, helium (He) implantation, high energy implantation of neutrons or protons, or electron beam irradiation may be used to create the desired defect levels in the semiconductor structure of an FRD.

Current FRD manufacturing generally uses platinum (Pt) diffusion due to the lower leakage of platinum (Pt) at high temperatures when compared to using gold (Au) diffusion. However, manufacturers using modern 8” and 12” wafer fabrication equipment to manufacture power MOS devices often do not allow platinum diffusion in their facilities because platinum can contaminate MOSFETs. Therefore, manufacturers generally use older 6” wafer fabrication equipment for FRD manufacture, which reduces production capacity for FRDs. The reduced production capacity may result in shortages of FRDs. Accordingly, FRD structures and manufacturing techniques are needed that are more acceptable to modern wafer fabricators.

### BRIEF DESCRIPTION OF THE DRAWINGS

FIG. 1 shows a cross-sectional view of a fast recovery diode with a current limiting resistor (CLR-FRD) in accordance with an example of the present disclosure.

FIG. 2 shows an equivalent circuit diagram of the CLR-FRD of FIG. 1 during blocking and reverse recovery modes.

FIG. 3 shows an equivalent circuit diagram of the CLR-FRD of FIG. 1 during forward conduction.

FIGS. 4A and 4B respectively show a cross-sectional view and a plan view of an anode cell for a CLR-FRD in accordance with an embodiment of the present disclosure.

FIG. 5 shows a plan view of an embodiment of a CLR-FRD with a single active anode cell.

FIG. 6 shows a plan view of an embodiment of a CLR-FRD with multiple active anode cells.

FIG. 7 shows a plan view of an embodiment of a CLR-FRD including multiple sub-cells within an anode area.

FIG. 8 shows a plan view of an embodiment of a CLR-FRD including multiple stripe-shaped sub-cells within an anode area.

FIG. 9 shows a cross-sectional view of an embodiment of high voltage edge termination for a CLR-FRD in accordance with an embodiment of the present disclosure.

FIG. 10 is a flow diagram of a manufacturing process for a CLR-FRD in accordance with an embodiment of the present disclosure.

FIG. 11 shows a cross-sectional view of an embodiment of a CLR-FRD having a polysilicon current limiting resistor.

The drawings illustrate examples for the purpose of explanation and are not of the invention itself. Use of the same reference symbols in different figures indicates similar or identical items.

### DETAILED DESCRIPTION

In accordance with an aspect of the present disclosure, a fast recovery diode (FRD) has structure that can reduce reverse recovery current (Irmax) or charge (Qrr) without needing use of lifetime control or platinum diffusion in wafer fabs that manufacture the FRD. (Electron and hole minority carrier lifetime is defined as a time for injected electrons and holes filling the trap sites near conduction and valence bands to disappear, and a short lifetime means carriers after injections disappear faster thus stored charge is also less inside the diode and or other Bipolar transistors) An FRD may particularly include an integrated resistor, sometimes referred to herein as a current limiting resistor (CLR), that reduces the reverse recovery current and charge of the FRD. The integrated FRD with the CLR is sometimes referred to herein as a CLR-FRD.

In one example, a CLR-FRD includes a CLR made of polysilicon that defines a resistive path connecting a device electrode, e.g., metal anode, to the P-N diode of the FRD. The CLR may be lightly doped polysilicon sandwiched between insulating layers and disposed to contact the P-N diode through an opening in the underlying insulating layer and contact the device electrode through an opening in the overlying insulating layer. The doping and geometry of polysilicon layer may be selected to provide a resistance that suitably reduces the reverse recovery current of the FRD.

In another example, the CLR of an FRD may be fabricated using a resistive semiconductor region of one conductivity type partly overlying a semiconductor buried region of the opposite conductivity type. The buried region may be buried in an N or P diode region of a P-N diode and may have a conductivity type that is opposite of the conductivity type of the N or P diode region in which it is buried. The buried region can define the length of the current path from a device electrode, e.g., anode, of the FRD through the resistive semiconductor region to the P-N diode. The buried region may be shorted to the device electrode of the FRD to mitigate or eliminate the effects of parasitic bipolar transistors in the semiconductor structure. A manufacturing process for the integrated structure of the FRD does not require platinum diffusion that might generate contaminants affecting MOSFET fabrication that may be conducted subsequently or elsewhere in the same fabrication facility.

An FRD in accordance with one specific example of the present disclosure includes a first semiconductor structure including a first layer of a first conductivity type, e.g., N-type, and a second semiconductor structure including a second layer of a second (opposite) conductivity type, e.g., P-type, forming a diode junction with the first semiconductor structure. A resistive semiconductor region, e.g., a lightly doped region of the second conductivity type, forms a CLR that connects the second layer to an electrode of the FRD. A region of the first conductivity type may be buried in the second layer with at least a portion of the semiconductor resistive region overlying the buried region. A heavily doped contact region of the first conductivity type may connect the device electrode to the buried region. The buried region creates parasitic bipolar transistors in the semiconductor structure, but the connection of the buried region to the device electrode avoids negative effects of the parasitic bipolar transistors. A manufacturing process for the integrated structure of this FRD does not require platinum diffusion that might generate contaminants affecting MOSFET fabrication that may be conducted subsequently or elsewhere in the same fabrication facility.

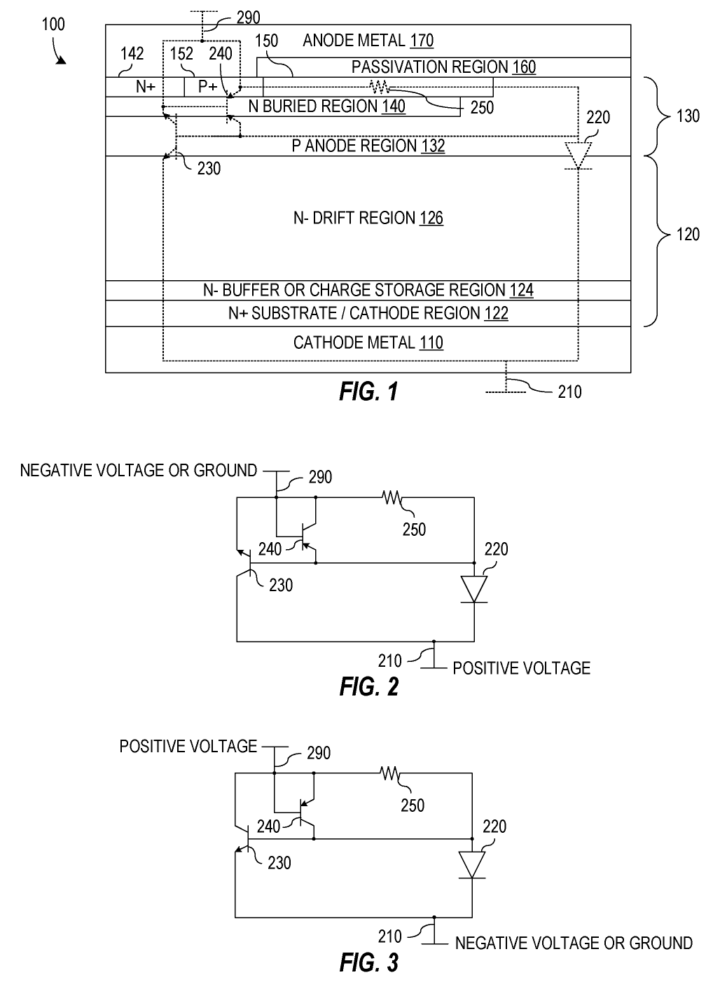

FIG. 1 shows a cross-section of a CLR-FRD 100 in accordance with one example of the present disclosure and shows an equivalent circuit diagram overlaid on the cross-section. CLR-FRD 100 in the example shown includes a metal layer 110 forming a cathode electrode on the bottom of a semiconductor cathode structure 120. In this specific example, semiconductor cathode structure 120 includes an N+ substrate or cathode region 122, an N- charge storage region 124, and an N- drift region 126. Charge storage region 124 may assist in providing soft recovery in CLR-FRD 100 In particular, during reverse recovery of the diode, meaning when diode voltage polarity changes from forward bias mode to reverse biased mode, the reversed bias creates depletion by sweeping stored carrier towards anode and cathode. Stored holes move toward the anode and stored electrons move toward the cathode, which forms the reverse recovery current. The reverse recovery current continues until charge carriers are removed from the depletion region. Diodes are designed to deplete the drift region completely. If no stored charge remains in the vicinity of depletion edge, reverse recovery current goes down to zero and reverse recovery voltage reaches its peak value. At this time, circuit parasitic elements such as inductance and capacitance may cause a voltage spike and oscillations across the diode. The n type charge storage region 124 may be more heavily doped to stops depletion from being too rapid, but not too heavily doped to store some injected carriers, so that the stored carriers diffuse from charge storage region 124 into the drift region to conduct some current while reverse bias voltage reaches its maximum. This current conduction makes reverse recovery current to drop to zero level after the reverse bias voltage reaches its maximum and thus prevents voltage pike. Also, the first half of the reverse recovery time may be equal to or shorter than the second half of the reverse recovery current. Drift region 126 may be lightly doped to provide high voltage blocking, but semiconductor cathode structure 120 may not require charge storage region 124 or drift region 126 in some cases. Also, FIG. 1 shows conductivity types of semiconductor regions and identifies regions as corresponding to cathode or anode structures to provide an example, but the illustrated cathode/anode or N/P conductivity types shown in FIG. 1 and described herein could be reversed in alternative examples.

A semiconductor anode structure 130 is on cathode semiconductor structure 120. Semiconductor anode structure 130 includes a P anode region 132 that forms a P-N junction (diode 220) with semiconductor cathode structure 120. An N-type buried region 140, i.e., a region of the conductivity type opposite from the conductivity type of region 132, is buried in semiconductor anode structure 130. Buried region 140 extends below a resistive region 150 and a P+ contact region 152. In the illustrated example, resistive region 150 may be a lightly-doped or P- semiconductor region. An N+ contact region 142 electrically connects buried region 140 to an overlying anode metal layer 170, and P+ contact region 152 electrically connects one end of resistive region 150 to anode metal layer 170. An insulating or passivation region 160 overlies resistive region 150, so that a current for a forward biased mode of CLR-FRD 100 flows from anode metal layer 170 through P+ contact region 152 and resistive region 150 to reach P anode region 132. Resistive region 150 may be a semiconductor region having a doping concentration and geometry, e.g., shape, length, width, and thickness, that are controlled to provide CLR 250 with a desired resistance.

Semiconductor structural parameters of CLR-FRD 100 may be adapted depending on electrical requirements such as the breakdown voltage and current capacity of CLR-FRD 100. As described further below, N-drift region 126 and P anode regions 132 may be epitaxial layers of silicon formed on an N+ silicon substrate that forms N+ cathode region 122. Typically, N- drift region 126 may have a thickness between 20 microns to 100 microns and may have a doping concentration between 5e13 cm-3 to 1e15 cm-3 depending on the required breakdown voltage. P anode region 132 may be between 3 microns and 10 microns deep and have a doping concentration between 1e16 cm-3 and 5e18 cm-3. In one specific example for a 750V FRD, N- drift region 126 may be about 55um thick and may have a doping concentration of about 1.2e14 cm⁻³ of an N-type dopant such as phosphorous, and P anode region 132 may be about 8 um deep and may have a doping concentration of about 1e17 cm-2 surface concentration of a P-type dopant such as boron.

Overlaid on the cross-section of FIG. 1 is a circuit equivalent of CLR-FRD 100 for illustration of switching performance of CLR-FRD 100 and possible impacts of parasitic circuit elements. In particular, buried region 140 creates an NPN bipolar transistor 230 and a PNP bipolar transistor 240. The equivalent circuit for CLR-FRD 100 thus includes diode 220, NPN bipolar transistor 230, PNP bipolar transistor 240, and current limiting resistor 250.

FIGS. 2 and 3 show the equivalent circuit of CLR-FRD 100 during application of different bias voltages. FIG. 2 particularly shows the equivalent circuit of CLR-FRD 100 in a blocking mode or a reverse recovery mode. In FIG. 2, an anode 290 of CLR-FRD 100 is grounded or has a negative voltage, while a positive voltage is applied to a cathode 210. FIG. 3 shows the equivalent circuit during forward conduction mode in which anode 290 is positively biased and cathode 210 is grounded or negatively biased.

Comparing FIGS. 2 and 3, the emitter and collector electrodes for NPN transistor 230 and PNP bipolar transistor 240 are reversed. FIG. 2 shows that during the blocking mode, N+ region 142 and N buried region 140 shown in FIG. 1 act as the emitter, P anode region 132 acts as the base, and N drift region 126 acts as the collector of the NPN BJT 230. P-type CLR 250 electrically shorts base and emitter of NPN BJT 230 thus prevents NPN BJT 230 from turning on, and NPN BJT 230 acts like a diode (P base 132 and N- drift/N+ 120). During the reverse recovery mode, electrons can be injected into P anode region 132 as a result of hole injection into N+ and N regions of semiconductor cathode structure 120, which softens the recovery without needing an N type charge storage region. The dimensions and dopant concentrations of P anode 132, N buried layer 140, and CLR resistor 150 may be tuned or optimized for proper operation of CLR-FRD during very high-speed switching cases at desired voltages and currents. For example, higher CLR resistance and lower P anode doping concentration may provide FRD recovery that is shorter for fast switching by increasing forward diode voltage Vf, which is not critical for fast switching.

FIG. 3 shows the equivalent circuit of the CLR-FRD 100 during forward conduction mode of operation in which anode 290 is positively biased relative to cathode 210. In forward conduction mode, N+ and N buried regions 142 and 140 act as the collector and N-drift region 126 acts as the emitter for NPN BJT 230. CLR 250 electrically shorts the collector to the base of NPN BJT 230. On the other hand, P+ region 152 acts as an emitter, P anode region 132 acts as a collector, and N+ region 142 and N buried region 140 act as a base for PNP BJT 240. The base and emitter of PNP BJT 240 are electrically shorted by anode metal 170 therefore PNP BJT 240 is off. As a result, injected holes from P+ anode 152 that flow through P- CLR 150 and by way of P anode region 132 are injected into N- drift region 126 and cause electron injection from the N+ cathode 122 via N- drift region 126. At a given forward bias voltage, the voltage drop across P- CLR 150 limits hole injection. The resistance value of the P- CLR 250, e.g., a boron implant dose of P- CLR region 150, can be adjusted to control the amount of hole injection and as a result control stored electron and hole pairs in the N- drift region 126, charge storage region 125, and P anode region 132. When needed for a fast-switching FRD, the boron implant dose may be reduced for P- CLR region 150.

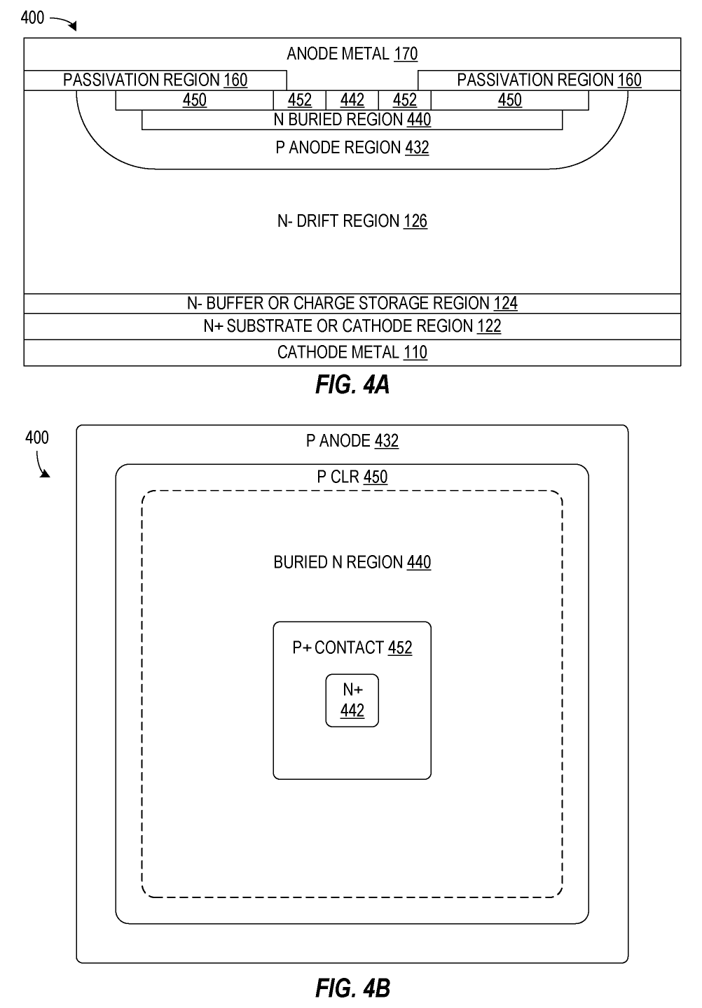

A CLR-FRD according to some embodiments disclosed herein may employ different layouts or plans that may organize a vertical CLR-FRD using one or more cells. FIGS. 4A and 4B respectively show a cross-sectional view and a plan view of a CLR-FRD cell 400 in accordance with an embodiment of the disclosure. CLR-FRD cell 400 may include a cathode metal 110 on a bottom of an N-type semiconductor structure including a N+ cathode region 122, an N- charge storage region 124, and an N- drift region 126 such as described above with reference to FIG. 1. Similarly, an anode structure of CLR-FRD 400 includes a P anode region 432, an N buried region 440 with an N+ contact region 442, a P- CLR region 450, and a P+ contact region 452. Unlike FIG. 1, FIGS. 4A and 4B show a boundary of P anode region 432 and illustrate how P- CLR region 450 may have a ring shape extending in all lateral directions from P+ contact region 452. P+ contact region 452 also has a ring shape and surrounds N+ contact region 442, while N+ contact region 142 extends vertically to N buried region 140. Anode metal 170 contacts contact regions 442 and 452 through an opening in passivation region 160.

FIG. 4B illustrates the example in which CLR-FRD 400 has a substantially square or rectangular layout, but the layout of CLR-FRD 400 may alternatively have other shapes such as hexagonal, circular, or annular to name a few. For example, the outer perimeters of the ring shapes of contact region 452 and CLR region 450 may be generally square or rectangular as shown in FIG. 4B or may have any other desired shape such as circular or hexagonal.

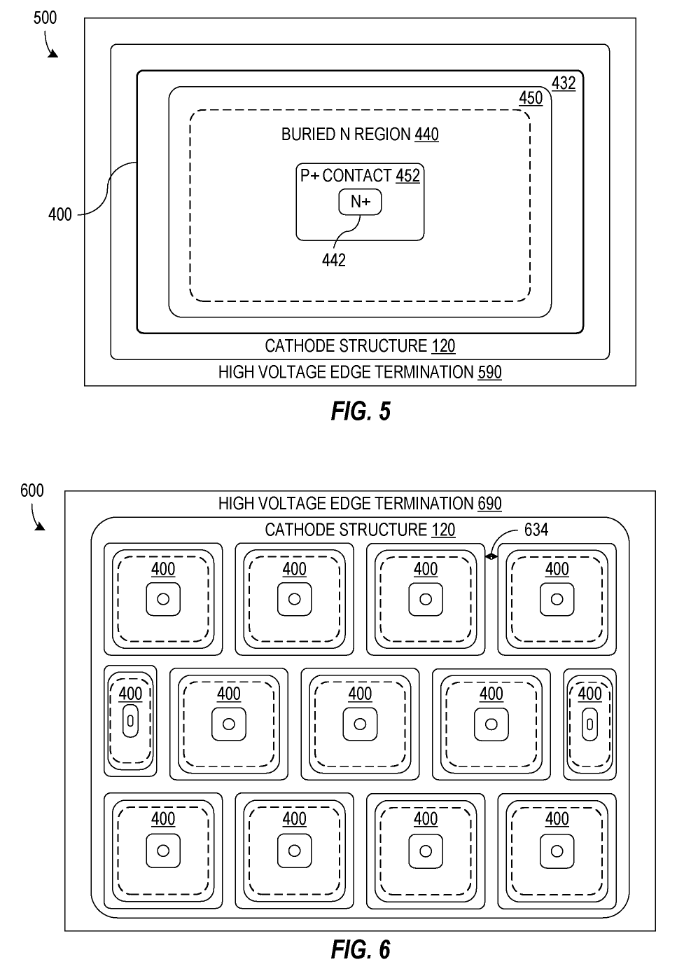

FIG. 5 shows a plan view of a CLR-FRD 500 including a single CLR-FRD cell 400. FIG. 5 also illustrates that a high voltage edge termination structure 590 may surround CLR-FRD cell 400 and its underlying semiconductor cathode structure 120. An example of a suitable high voltage edge termination structure is described further below.

An alternative layout for a CLR-FRD may include multiple CLR-FRD cells. FIG. 6, for example, shows a CLR-FRD 600 that includes multiple rectangular CLR-FRD cells 400. The multiple cells and gaps between P anode regions may help limit the breakdown voltage of CLR-FRD 600. For example, increasing the gap between the P anodes of the CLR-FRD cells can reduce breakdown voltage of the CLR-FRD cells below the breakdown of the edge termination region 690. In the example of FIG. 6, CLR-FRD cells 400 are substantially rectangular, vary in size, and are arranged to limit the straight-line lengths of gaps between the CLR-FRD cells 400. CLR-FRD cells 400 could be arranged in orthogonal rows and columns, however, FIG. 4 shows an off-set type arrangement, which may minimize the difference between the corner-to-corner gaps compare to side to side gaps of the CRL-FRD cells 400. Alternatively, the cells 400 may have any desired shape, e.g., a strip, hex, square, triangular, or circular shape, with large enough gaps between the adjacent cells to lower the breakdown compared to the breakdown voltage of a high-voltage edge termination 690 surrounding the cells 400 and the cathode structure 120.

A CLR-FRD device may be desired that has a breakdown voltage limited by the active area rather than by the high voltage edge termination. A gap 632 between the cells 400 in CLR-FRD 600 may be selected to achieve lower breakdown voltage in P anode cells 400 than in high voltage edge termination 690. For example, gap 634 may be between 5 to 15 microns if CLR-FRD 600 has a 750V breakdown.

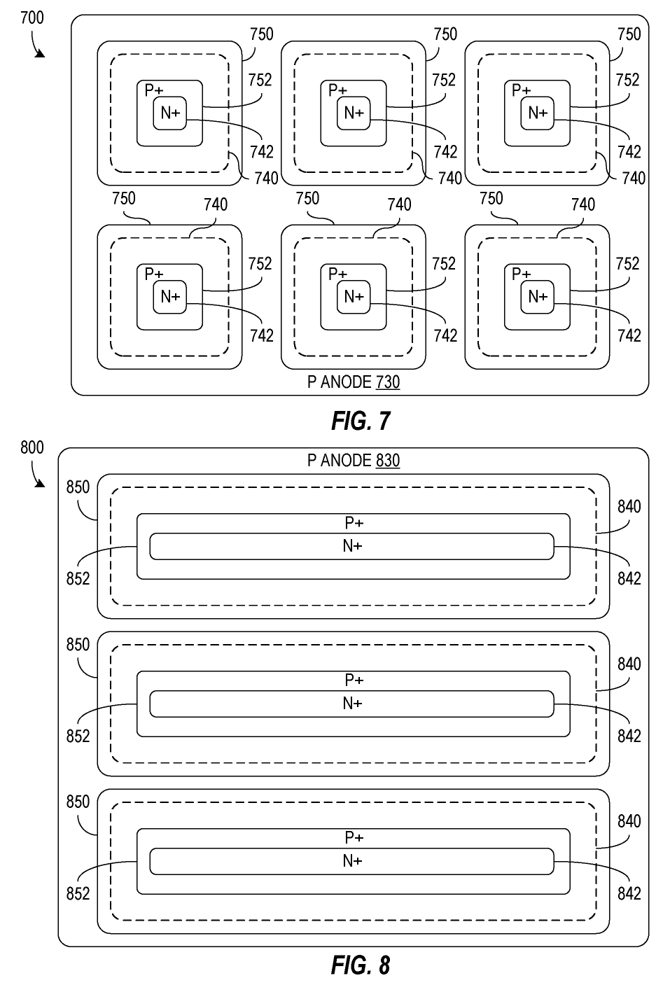

CLR-FRD 600 is an example having a multiple semiconductor anode cells 400, each cell 400 including a separate P anode region 432 and a CLR region 450. FIGS. 7 and 8 show CLR-FRDs 700 and 800, each including a large rectangular P anode cell 730 or 830 with smaller square or stripe sub-cells including N buried regions and P CLRs.

FIG. 7 particularly illustrates CLR-FRD 700 having a semiconductor P anode region 720 containing multiple N buried regions 740. N buried region 740 has an overlying N+ contact region 742 and an overlying P+ contact region 752. Each P+ contact region 752 has a P CLR region 750 extending over and beyond its N buried region 740 to semiconductor P anode region 730. CLR-FRD 700 uses an array of squared sub-cells in a common semiconductor P anode region 730.

FIG. 8 shows a plan view of CLR-FRD 800 that uses stripe-shaped sub-cells in a common semiconductor P anode region 830. Each stripe-shaped sub-cell includes an N buried region 840 has an overlying N+ contact region 842 and an overlying P+ contact region 852, both of which are also stripe shaped. Each P+ contact region 852 has a P CLR region 850 extends over and beyond its N buried region 840 to semiconductor P anode region 830.

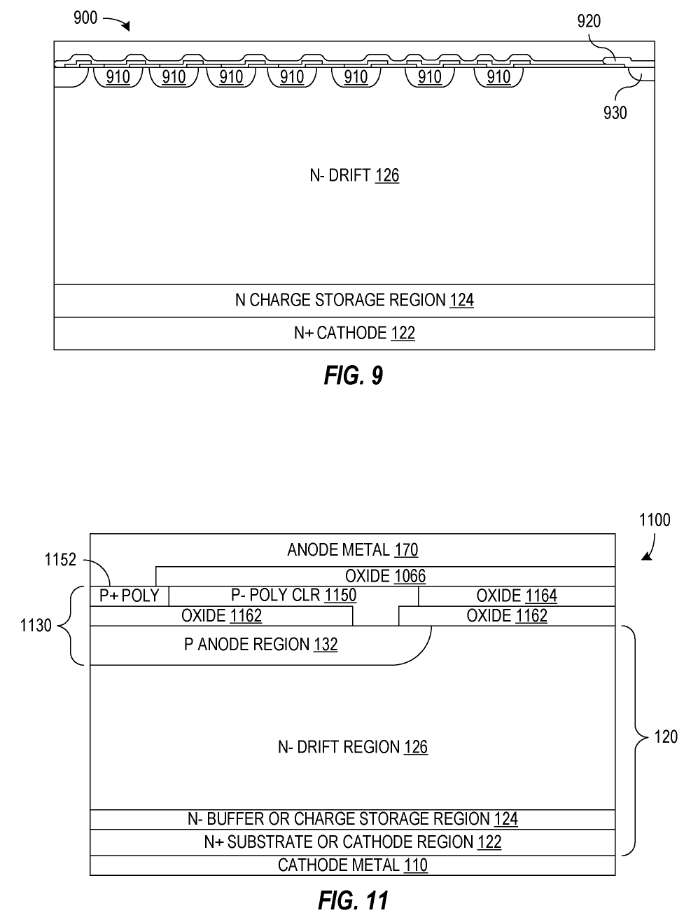

High voltage termination is generally needed around active areas of an FRD or CLR-FDR. FIG. 9 shows a Floating Field Rings and Field Plates type High Voltage Edge Termination 900 for a CLR-FRD using the P anode as field rings. To provide high voltage blocking, edge termination structure 900 may surround the active area of the CLR-FRD. In the example of FIG. 9, termination 900 may include P-type rings 910 that may surround or encircle the active area of the CLR-FRD. P rings 910 may have increasing ring spacing from inner rings toward the die edge. Additionally, a field plate 920 and an N+ channel stop 930 may be employed. P rings 910 control and distribute the electric field in the edge region, so that the active region controls break down. Field plate 920 and an N+ channel stop 930 that may be used to ensure that depletion does not extend to the cut edge of the die. Other high voltage edge termination types such as Junction Termination Extension (JTE)and Multiple Zone JTE type, which are known in the art, may alternatively be employed.

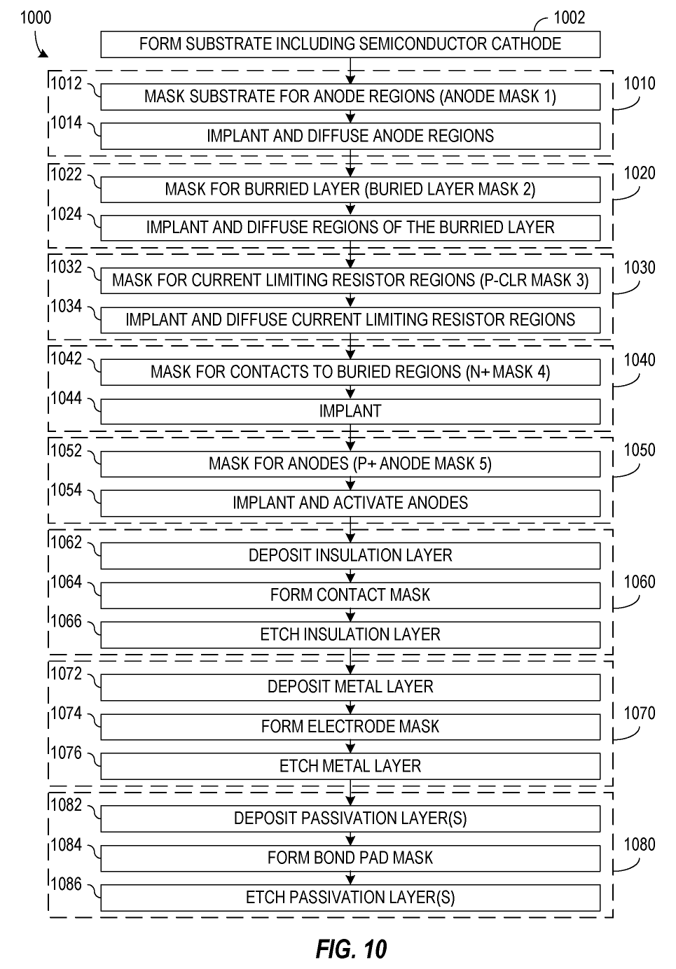

FIG. 10 is a flow diagram of a manufacturing process 1000 for a CLR-FRD in accordance with an embodiment of the present disclosure. Process 1000 may begin with a cathode fabrication process 1002 fabricating a cathode structure, e.g., cathode structure 120 described above. Process 1002 may, for example, include epitaxially growing a buffer or charge storage region, e.g., N- buffer or charge storage region 124, of doped silicon and a drift region, e.g., drift region 126, of doped silicon on a silicon substrate, e.g., substrate 122. In general, the doping concentrations and the thicknesses of the substrate and the epitaxial layers depend on the requirements of the CLR-FRD being manufactured, particularly on the breakdown voltage. In one example, the silicon substrate has an N+ doping of about 1e19 cm⁻³ to 5e19 cm⁻³ of CLR-FRD, the buffer or charge storage region has a thickness of about 4 microns to 10 microns and an N- doping of about 5e15 cm⁻³ to 1e17 cm⁻³, and the drift region has a thickness of about 20 microns to 100 microns and an N- doping of about 1e15cm-3 to 4e13 cm-3.

A series of masks and implantation, deposition, or etching processes may be performed on the substrate on which the drift region was grown. A first mask process or P anode mask process 1010 may form P anode regions in the N-drift region. The P anode mask process 1010 may include a mask formation process 1012 forming the P anode mask. The P anode mask may be formed using a thick photoresist and field oxide and may define locations, shapes, and sizes of P Anode regions. A high energy boron ion implantation 1014 may implant boron (B) with multiple implant energies ranging from 30 KeV to 2 MeV and a dose ranging from 5e12 cm⁻² to 5e13 cm⁻². Boron diffusion at 1150 to 1200 ºC for 3 to 5 hours may then be performed with range targeting a 6 to 8 microns junction depth inside the N- drift region.

A second mask process or N buried layer mask process 1020 may form N regions buried in the P anode regions. A photolithographic process 1022 forms a mask that defines areas of the N buried layer regions. An implantation process 1024 may implant an N-type dopant such as phosphorous (P) with an ion implant dose ranging 5e12 to 3e13 cm⁻² and may use multiple implant energies ranging from 40 KeV to 1 MeV, and a diffusion process may keep the structure at 1000 to 1150 ºC for about 30 to 120 minutes to achieve 1 to 2 microns deep N junctions within the P anode regions.

A third mask process or P CLR mask process 1030 may form the current limiting resistors. A photolithographic process 1032 may form a photoresist mask that defines the P CLR regions for an ion implantation process 1034. Ion implantation process 1034 may implant a P-type dopant such as boron (B) at a dose ranging from 5e12 cm⁻² to 5e13 cm⁻² with implant energy ranging from about 20 to 60 KeV. Multiple different energy levels may be used. P CLR layer junction may be at a depth ranging 0.2 to 1um after an activation process 1036. Activation process 1036 may subject ion implanted wafers to 900 C to 1100 C temperature by using diffusion tubes or Rapid Thermal Annealing (RTA) to make implanted species in silicon as dopants such as boron becomes P type and phosphorous becomes N type dopants. Additionally, this activation or temperature treatment also repairs implant induced damage in the silicon underlying N buried layer.

A fourth mask process or N+ mask process 1040 may form contacts to the regions of the buried layer. A photolithographic process 1042 forms a mask defining contact regions, which an implantation process 1044 into P anode regions may form using an N-type dopant, e.g., phosphorous, at a dose ranging from 1e15 cm⁻² to 5e15 cm⁻² with 60 to 80 KeV energy

A fifth mask process or P+ anode mask process 1050 may form P+ anode regions. In the fifth mask process 1050, a photolithographic process 1052 may form a photoresist mask defining areas of the P+ anode regions that will be used to make ohmic contact to P CLR regions. An ion implantation process 1054 may implant BF2 into the P anode regions, through the P+ anode mask using an implant dose ranging from 1e14 cm⁻² to 5e15 cm⁻². The BF2 may then be activated by a temperature treatment in the range of 900 ºC to 1100 ºC.

A sixth mask process or a contact mask process 1060 forms an insulating layer with windows or openings for contacting the N+ and P+ contacts. The contact mask process 100 may include an insulation deposition process 1062 that deposits a layer of insulating material such as borophosphosilicate glass (BPSG) about 0.5 microns thick. A masking process 1064 defines the locations of the windows or openings, and an etch process 1066 creates the windows or openings in the insulating layer.

A seventh mask process or metal mask process 1070 may form an anode electrode of the CLR-FRD and field plates of the high voltage edge termination region. Metal mask process 1070 may include metal deposition process 1072 to deposit a metal, e.g., Ti/TiN and Al:Cu or Al:Si:Cu by sputtering or other deposition process and thereby form a layer at least 4-micron metal thickness. A photolithographic process 1074 may form a photoresist mask on the metal layer, and an etch process 1076 may form the anode electrode and the field plates.

An eighth mask process or passivation mask process 1080 may for a passivation layer that exposes the anode electrode. After metallization in process 1070, a deposition process 1082 may deposit one or more inorganic passivation layer, e.g., an oxide passivation layer, and one or more organic passivation layer, e.g., polyimide. A spin on method, for example, may form a polyimide layer. A mask process 1084 and an etch process 1086 may remove the passivation layer from an anode bonding pad area. In some cases, removal of inorganic passivation and organic passivation may use different masks.

FIG. 11 shows an embodiment of a CLR-FRD 1100 that includes a current limiting resistor 1150 made of polysilicon, e.g., lightly doped or P- polysilicon. CLR-FRD 1100 also includes P+ polysilicon region 1152 as a P+ anode, which connects to the P-type poly region Current Limit Resistor (CLR) 1150. As shown in FIG. 11, P- polysilicon CLR 1150 and P+ polysilicon anode 1152 may overly an insulating, e.g., oxide, layer 1162 with an end of P- polysilicon CLR 1150 contacting P anode region 132 through an opening in oxide layer 1162. P- polysilicon CLR 1150 and P+ polysilicon anode region 1152 may have any of the layouts described above or illustrated in FIGS. 5, 6, 7, or 8, and insulating layers 1164 and 1166 may be formed around and above P- polysilicon CLR 1150 and P+ polysilicon anode region 1152 to define where the anode electrode 170 contacts P+ polysilicon anode region 1152. The cathode structure 120 of CLR-FRD 1100 may be as described above.

The hole injection level and thus stored charge within CLR-FRD 1100 may be controlled by doping concentrations in P+ polysilicon anode 1152, P polysilicon CLR 1150, and P anode regions 132 and also by the thickness and the length of P polysilicon CLR 1150. Polysilicon thickness for CLR 1150 and polysilicon anode 1152 may range from about 0.3 to 1.5 microns. Implant dose of P polysilicon CLR ranges from about 5e12 cm⁻² to 5e14 cm⁻². P+ polysilicon anode 1152 may have an implant dose in a range from about 5e13 cm⁻² to 5e15 cm⁻².

Although particular implementations have been disclosed, these implementations are only examples and should not be taken as limitations. Various adaptations and combinations of features of the implementations disclosed are within the scope of the following claims.

What is claimed is:

1. A fast recovery diode comprising:
a first semiconductor structure comprising a first layer having a first conductivity type;
a first electrode of the fast recovery diode, the first electrode contacting a bottom surface of the first layer;
a second semiconductor structure including a second layer having a second conductivity type, the second layer contacting the first semiconductor structure to form a junction;
a second electrode of the fast recovery diode, the second electrode overlying the second semiconductor structure;
a resistive semiconductor region comprising polysilicon, the resistive semiconductor region providing a current path between the second electrode and the second semiconductor structure;
a first insulating layer on the second semiconductor structure, the resistive semiconductor region overlying a portion of the first insulating layer and contacting the second semiconductor layer through a first opening in the first insulating layer; and
a second insulating layer on the resistive semiconductor region, the second electrode contacting the resistive semiconductor region through a second opening in the second insulating layer.

2. The fast recovery diode of claim 1, wherein the first conductivity type is N-type, and the second conductivity type is P-type.

3. The fast recovery diode of claim 2, wherein the resistive semiconductor region includes P+ polysilicon anode region and P polysilicon region.

4. The fast recovery diode of claim 3, wherein the P+ polysilicon anode region electrically connects the second electrode and the P polysilicon region through the second opening in the second insulating layer.

5. The fast recovery diode of claim 4, wherein the second semiconductor layer forms P anode of the fast recovery diode, the P polysilicon region being electrically connected to the P anode through the first opening in the first insulating layer.

6. The fast recovery diode of claim 5, wherein the P anode is a single region covering 100% of an active region excluding high voltage termination.

7. The fast recovery diode of claim 1, wherein the second layer comprises multiple P anode cells that are separated from each other.

8. The fast recovery diode of claim 7, wherein each of the P anode cells is shaped as one of a stripe, a hexagon, a square, a circle, and a rectangle.

9. The fast recovery diode of claim 7, further comprising a high voltage edge termination region including field limiting rings encircling the P anode cells.

10. The fast recovery diode of claim 1, wherein the first insulating layer and the second insulating layer are oxide layers.

11. The fast recovery diode of claim 1, wherein the first electrode is a cathode of the fast recovery diode, and the second electrode is an anode of the fast recovery diode.

12. The fast recovery diode of claim 1, wherein the second electrode comprises at least one material selected from a group consisting of Al:Cu, and Al:Cu:Si.

13. The fast recovery diode of claim 1, wherein thickness of the resistive semiconductor region is in the range of about 0.3 to 1.5 microns.

14. The fast recovery diode of claim 3, wherein P-type implant dose of P polysilicon region of the resistive semiconductor region is in the range of about 5e12 cm⁻² to 5e14 cm⁻².

15. The fast recovery diode of claim 3, wherein P-type implant dose of P+ polysilicon anode region of the resistive semiconductor region is in the range of about 5e13 cm⁻² to 5e15 cm⁻².
